(19) United States
(12) Patent Application Publication
(10) Pub. No.: US 2026/0372026 A1
(43) Pub. Date: Nov. 19, 2026

(54) SUBSTRATE MANUFACTURING METHOD, CHIP MANUFACTURING METHOD, AND PROCESSING DEVICE

(71) Applicant: DISCO CORPORATION, Tokyo (JP)

(72) Inventor: Yuya KUMAGAI, Tokyo (JP)

(21) Appl. No.: 19/657,880

(22) Filed: Apr. 24, 2026

(30) Foreign Application Priority Data
May 16, 2025 (JP) 2025-082370

(51) Int. Cl. H10P 90/00; B24B 9/06; H10P 58/00

(52) U.S. Cl. CPC H10P 90/123; B24B 9/065; H10P 58/00; H10P 90/128

(57) ABSTRACT

A substrate manufacturing method for manufacturing a substrate thinner than a workpiece having a main surface and a side surface from the workpiece includes: separating the substrate from the workpiece; forming a chamfered portion at a boundary between a sliced surface and a side surface of the separated substrate; and grinding the sliced surface with a grinding wheel. The forming is performed after the separating and before the grinding or during the grinding, and in the grinding, the sliced surface of the substrate on which the chamfered portion is formed is ground.

### CROSS-REFERENCE TO RELATED APPLICATIONS

This application is based on and claims priority under 35 USC 119 from Japanese Patent Application No. 2025-082370 filed on May 16, 2025, the contents of which are incorporated herein by reference.

### TECHNICAL FIELD

The present disclosure relates to a substrate manufacturing method, a chip manufacturing method, and a processing device.

### BACKGROUND

As a method for manufacturing a substrate made of a semiconductor material or the like, Japanese Patent Application Laid-Open Patent Publication No. 2016-111143 discloses a method in which a laser beam having a transmission wavelength is focused and emitted from a front surface side of an ingot made of a semiconductor material to form a peeling layer inside the ingot, and then a plate-shaped object is peeled off from the ingot to generate a substrate.

As a method for grinding a substrate after being peeled, Japanese Patent Application Laid-Open Patent Publication No. 2009-176848 discloses a method for improving the biting of a grinding stone during finish grinding by grinding a grinding surface of a substrate by rough grinding with an inclination angle and then grinding the grinding surface to be flat by finish grinding.

In Japanese Patent Application Laid-Open Patent Publication No. 2009-176848, when the grinding surface of the substrate is ground by rough grinding with the inclination angle, the substrate is ground by an amount corresponding to the inclination angle at the time of finish grinding, resulting in an increased loss of material.

The present disclosure provides a substrate manufacturing method, a chip manufacturing method, and a processing device capable of decreasing a loss of material when a substrate is manufactured from a workpiece.

### SUMMARY

A first aspect of the present disclosure relates to a substrate manufacturing method for manufacturing a substrate thinner than a workpiece having a main surface and a side surface from the workpiece. The substrate manufacturing method includes: separating the substrate from the workpiece; forming a chamfered portion at a boundary between a sliced surface and a side surface of the separated substrate; and grinding the sliced surface with a grinding wheel. The forming is performed after the separating and before the grinding or during the grinding, and in the grinding, the sliced surface of the substrate on which the chamfered portion is formed is ground.

A second aspect of the present disclosure relates to a chip manufacturing method includes: manufacturing a substrate by using the substrate manufacturing method described above; manufacturing a plurality of semiconductor devices on the substrate; and manufacturing a semiconductor chip by cutting the substrate on which the plurality of semiconductor devices are formed.

A third aspect of the present disclosure relates to a processing device for processing a sliced surface of a substrate separated from a workpiece having a main surface and a side surface. The processing device includes: a chamfered portion forming device configured to form a chamfered portion at a boundary between the sliced surface and a side surface of the separated substrate; and a grinding device configured to grind the sliced surface with a grinding wheel. The chamfered portion forming device forms the chamfered portion before the substrate is ground by the grinding device or during grinding of the substrate by the grinding device, and the grinding device grinds the sliced surface of the substrate on which the chamfered portion is formed.

### BRIEF DESCRIPTION OF DRAWINGS

Exemplary embodiments of the present disclosure will be described in detail based on the following figures, wherein

FIG. 1 is a schematic view of an ingot and a substrate manufactured from the ingot;

FIG. 2 is a flowchart of a substrate manufacturing method according to an embodiment of the present disclosure;

FIG. 3 is a block diagram illustrating a configuration of a substrate manufacturing device;

FIG. 4 is a diagram illustrating a laser beam emitting mechanism;

FIG. 5 is a diagram illustrating a peeling layer forming step;

FIG. 6 is a diagram illustrating a peeling step;

FIG. 7 is a diagram illustrating an example of a chamfering step (part 1);

FIG. 8 is a diagram illustrating an example of the chamfering step (part 2);

FIG. 9 is a diagram illustrating another example of the chamfering step;

FIG. 10 is a diagram illustrating a grinding step;

FIG. 11 is a diagram illustrating a relation between a length of a chamfered portion in a thickness direction of the substrate and a grinding amount in the grinding step;

FIG. 12 is a diagram illustrating a polishing step;

FIG. 13 is a flowchart of a chip manufacturing method according to an embodiment of the present disclosure; and

FIG. 14 is a front view of the substrate on which a semiconductor device is formed.

### DESCRIPTION OF EMBODIMENTS

Hereinafter, an embodiment of a substrate manufacturing method, a chip manufacturing method, and a processing device of the present disclosure will be described with reference to the accompanying drawings.

### Workpiece and Substrate

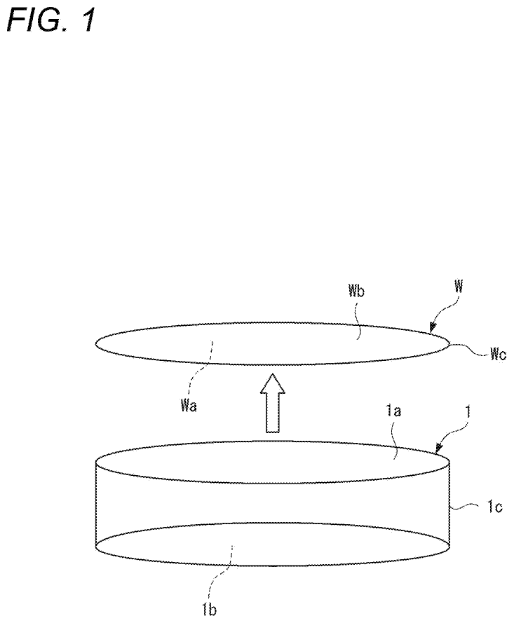

As illustrated in FIG. 1, in the substrate manufacturing method of the present embodiment, a substrate W thinner than an ingot 1 as an example of a workpiece is manufactured from the ingot 1.

The ingot 1 is formed, for example, in a columnar shape and has main surfaces (front surface 1a and back surface 1b) and a side surface 1c. The ingot 1 is made of a semiconductor material, and is, for example, an ingot made of silicon carbide (SiC), gallium nitride, gallium oxide, or silicon nitride. The ingot 1 is not limited to a single crystal ingot and may be a polycrystalline ingot.

The substrate W is peeled off from a front surface 1a of the ingot 1, whereby the substrate W (that is, a wafer), which is a plate-shaped object, is manufactured. In FIG. 1, reference number Wa attached to the substrate W is a sliced surface (hereinafter, referred to as a sliced surface Wa) which is a surface separated from the ingot 1, reference number Wb is a surface opposite to the sliced surface Wa, and reference number Wc is a side surface (hereinafter, referred to as a side surface Wc).

### Substrate Manufacturing Method

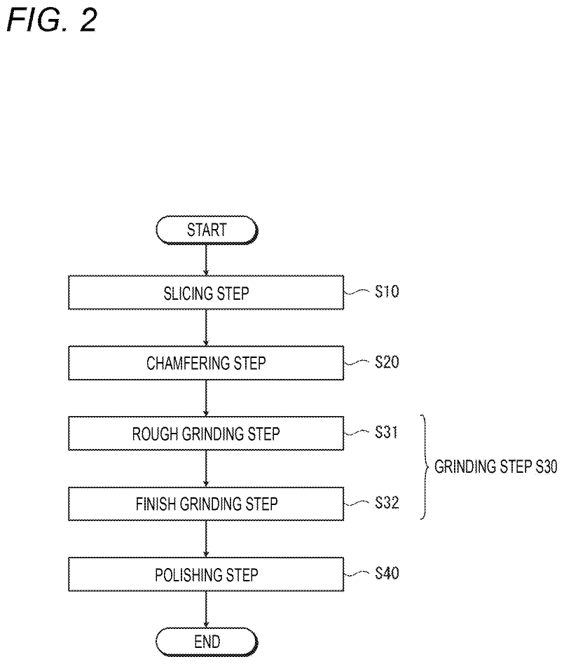

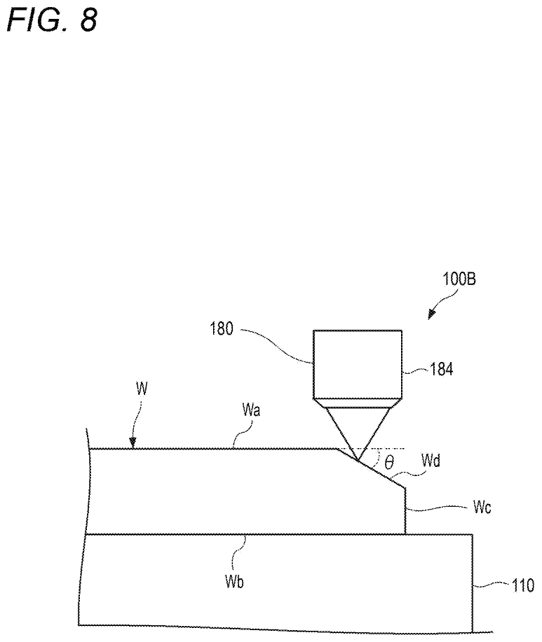

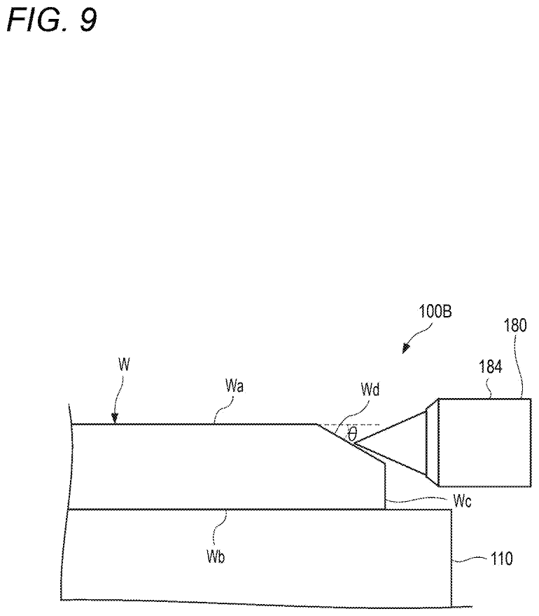

FIG. 2 is a flowchart of an embodiment of the substrate manufacturing method. The substrate manufacturing method includes a slicing step S10 of separating the substrate W from the ingot 1, a chamfering step S20 of forming a chamfered portion Wd (see FIGS. 8 and 9 and the like) on the substrate W, a grinding step S30 of grinding the substrate W, and a polishing step S40 of polishing the substrate W. The grinding step S30 includes a rough grinding step S31 and a finish grinding step S32.

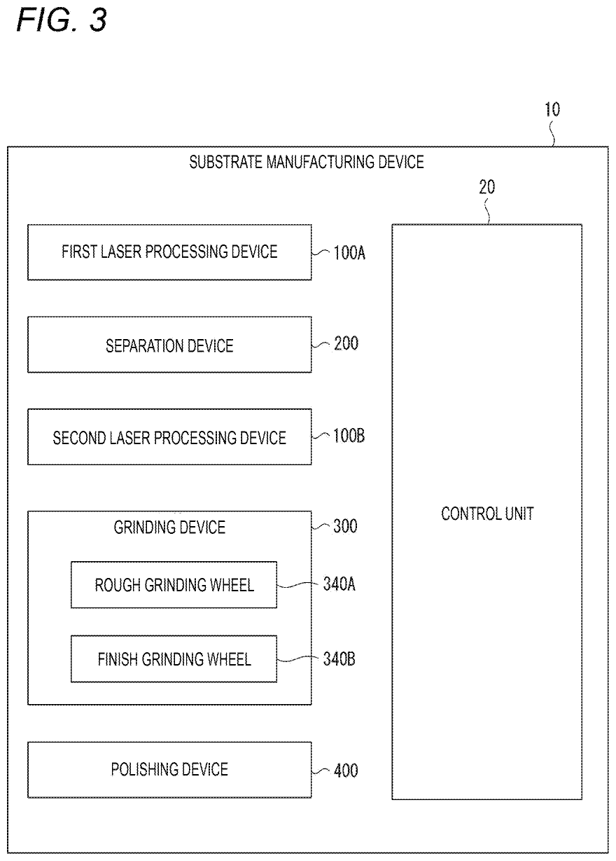

FIG. 3 is a block diagram illustrating a configuration of a substrate manufacturing device 10 used in the substrate manufacturing method. The substrate manufacturing device 10 includes a first laser processing device 100A, a separation device 200, a second laser processing device 100B, a grinding device 300, and a polishing device 400, and uses these devices to perform the above steps. Hereinafter, the configuration of the substrate manufacturing device 10 will be described in detail together with each step.

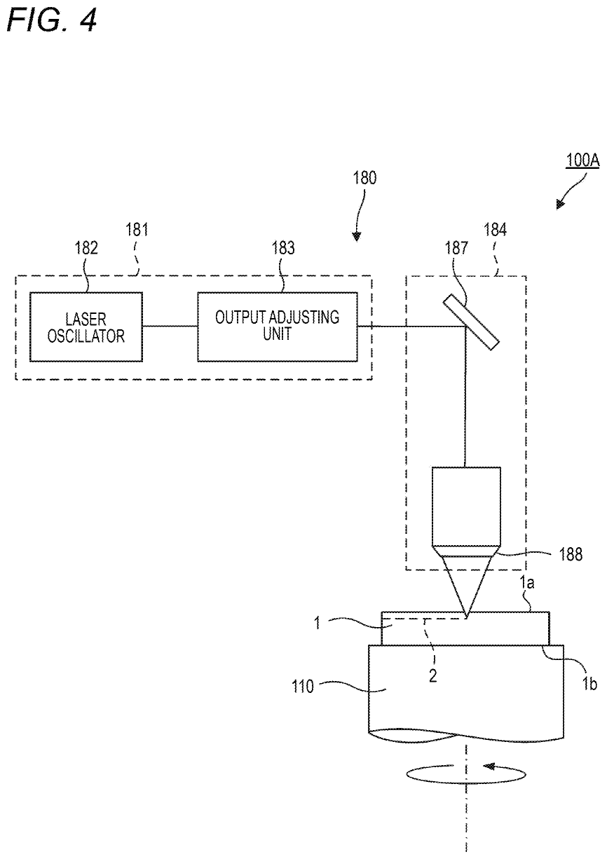

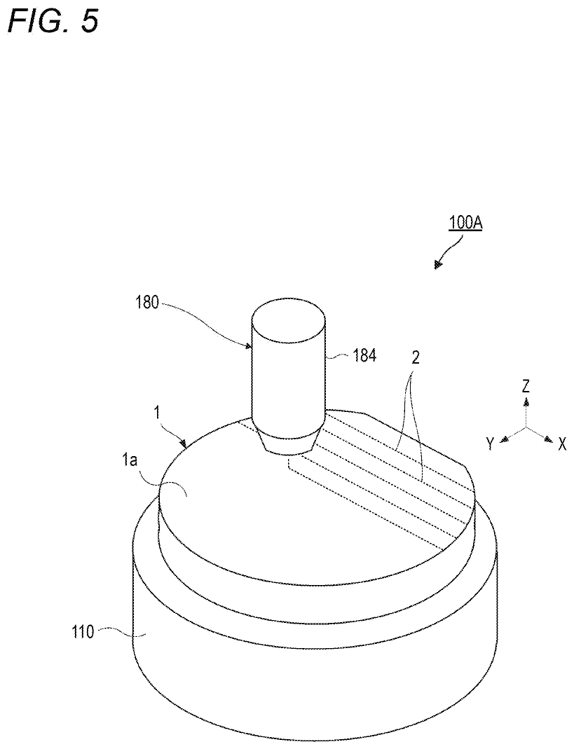

In the substrate manufacturing device 10, for example, the first laser processing device 100A, the separation device 200, the second laser processing device 100B, the grinding device 300, and the polishing device 400 may be integrally mounted on a common base, or at least one device may be separately mounted on another base. The first laser processing device 100A and the second laser processing device 100B may have the same configuration, and therefore, here, the configuration of the first laser processing device 100A will be representatively described, and the description of the configuration of the second laser processing device 100B will be omitted. Although the first laser processing device 100A will be described with reference to FIGS. 4 and 5, it is assumed that the components are common to the first laser processing device 100A and the second laser processing device 100B.

The substrate manufacturing device 10 further includes a control unit 20 that controls each device. The control unit 20 may be, for example, a known computer, including a processor that performs various calculations, a storage unit including a storage medium, and an input and output interface that controls input and output of data between the inside and outside of the control unit. The processor executes various programs stored in the storage unit. A plurality of control units 20 may be provided corresponding to the respective devices, or may be an integrated control unit that controls all the devices.

Although not illustrated, the substrate manufacturing device 10 further includes a plurality of conveyance devices that convey workpieces (ingot 1 or substrate W) between the devices. The configuration of each conveyance device is not particularly limited as long as it is a mechanism capable of appropriately conveying the workpiece, and for example, the conveyance may be implemented by a conveyor or by a robot arm.

### Slicing Step

In the slicing step S10, the substrate W is separated from the ingot 1 by laser processing for the ingot 1, wire saw processing, or the like. In the present embodiment, an example will be described in which the slicing step S10 is performed by the laser processing using the first laser processing device 100A.

The slicing step S10 includes a peeling layer forming step of emitting a laser beam having a wavelength that penetrates the ingot 1 from the front surface 1a of the ingot 1, positioning a focal point of the laser beam at a position deeper than the front surface 1a of the ingot 1, and processing and feeding the ingot 1 and the focal point relative to each other, thereby forming a peeling layer 2 (see FIG. 4 and the like) inside the ingot 1, and a peeling step of peeling off the substrate W from the peeling layer 2. The peeling layer 2 includes a plurality of modified regions formed inside the ingot 1 and cracks extending from the modified regions.

FIG. 4 is a schematic diagram of the first laser processing device 100A used in the peeling layer forming step. The first laser processing device 100A includes a laser beam emitting mechanism 180 that emits the laser beam, and a holding table 110 that suction-holds the ingot 1 that is a workpiece. The holding table 110 is connected to a rotation drive source (not illustrated) such as a motor, and is rotatable about a rotation axis perpendicular to a holding surface by operating the rotation drive source.

The laser beam emitting mechanism 180 includes a laser beam generating unit 181 and a condenser (laser head) 184. Although not illustrated, the laser beam emitting mechanism 180 further includes an imaging unit, including a microscope, a camera, and the like, adjacent to the condenser 184.

The laser beam generating unit 181 includes a laser oscillator 182 that oscillates a YAG laser or a YVO4 laser, and an output adjusting unit 183. The laser oscillator 182 has a Brewster window, and the laser beam emitted from the laser oscillator 182 is a linearly polarized laser beam.

The output adjusting unit 183 adjusts an output of the laser beam to a predetermined power. The laser beam whose output is adjusted is reflected by a mirror 187 of the condenser 184, and then emitted to the ingot 1 held on the holding table 110 at a focal point positioned inside the ingot 1 by a condenser lens 188.

In the peeling layer forming step, a laser beam is emitted from the front surface 1a of the ingot 1, the focal point of the laser beam is positioned at a position deeper than the front surface 1a, and the ingot 1 and the focal point are processed and fed relative to each other, thereby processing the inside of the ingot 1 and forming the peeling layer 2 inside the ingot 1. For example, in the peeling layer forming step, as illustrated in FIG. 5, a process is repeated in which the ingot 1 is processed and fed such that the focal point moves from one end to the other end of the ingot 1 along an X-axis direction to form modified regions and cracks along the X-axis direction, the ingot 1 is fed by a predetermined amount in a Y-axis direction, and then the ingot 1 is processed and fed such that the focal point moves from the other end to the one end of the ingot 1 along the X-axis direction to form modified regions and cracks along the X-axis direction. Accordingly, the peeling layer 2 is formed inside the ingot 1.

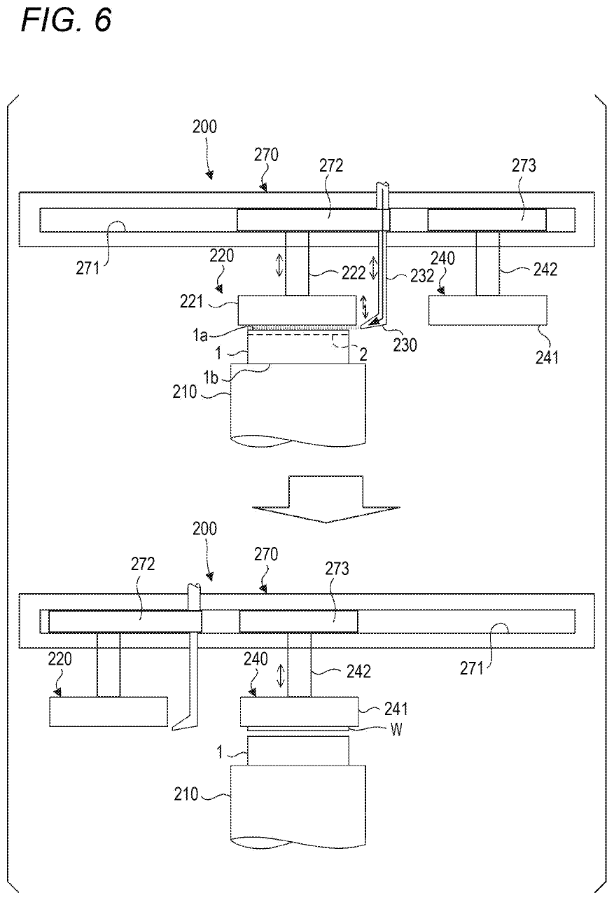

As illustrated in FIG. 6, the peeling step is a step of peeling off the substrate W from the peeling layer 2 formed on the ingot 1 by the separation device 200. An upper diagram in FIG. 6 is a diagram illustrating a state in which ultrasonic waves are applied to the ingot 1 in the peeling step, and a lower diagram in FIG. 6 is a diagram illustrating a state in which a substrate W is separated from the ingot 1 in the peeling step.

The separation device 200 includes a holding table 210 that suction-holds the ingot 1 with the front surface 1a of the ingot 1 facing upward, an ultrasonic oscillation unit 220 that applies ultrasonic waves to the ingot 1, a separation unit 240 that separates the substrate W from the ingot 1, and a moving mechanism 270 that moves the ultrasonic oscillation unit 220 and the separation unit 240 in a horizontal direction.

A rectangular opening 271 extending in the horizontal direction is formed in the moving mechanism 270, and a moving piece 272 supporting the ultrasonic oscillation unit 220, and a moving piece 273 supporting the separation unit 240 are movable along the opening 271. Although not illustrated, the moving mechanism 270 includes an actuator that moves the moving pieces 272 and 273 along the opening 271, and includes, for example, a ball screw coupled to the moving pieces 272 and 273, a motor that rotates the ball screw, and the like.

The ultrasonic oscillation unit 220 includes an ultrasonic transducer 221 that applies ultrasonic waves to the ingot 1, a liquid supply nozzle 230 that supplies a liquid (for example, pure water) between the front surface 1a of the ingot 1 and the ultrasonic transducer 221, a transducer lifting mechanism 222 that adjusts a vertical position of the ultrasonic transducer 221, and a nozzle lifting mechanism 232 that adjusts a vertical position of the liquid supply nozzle 230. Each of the transducer lifting mechanism 222 and the nozzle lifting mechanism 232 is an actuator implemented by a fluid cylinder operated by a fluid pressure such as air or oil, or implemented by a ball screw, a motor, and the like. The ultrasonic transducer 221 is positioned by the transducer lifting mechanism 222 at a position at which a small gap is provided between the ultrasonic transducer 221 and the front surface 1a of the ingot 1. While the ultrasonic waves are being applied to the ingot 1, the liquid supply nozzle 230 continuously supplies a liquid to the gap between the ultrasonic transducer 221 and the front surface 1a of the ingot 1 to form a liquid layer. The ultrasonic waves emitted from the ultrasonic transducer 221 are transmitted to the ingot 1 via the liquid layer, and extend the cracks of the peeling layer 2 formed in the ingot 1. Accordingly, a strength of the peeling layer 2 decreases.

The separation unit 240 includes a suction pad 241 that suction-holds the substrate W separated from the ingot 1, and a pad lifting mechanism 242 that adjusts a vertical position of the suction pad 241. The pad lifting mechanism 242 is an actuator implemented by a fluid cylinder, or implemented by a ball screw, a motor, and the like. After ultrasonic waves are applied to the entire front surface 1a of the ingot 1, the moving pieces 272 and 273 move, and the suction pad 241 moves to a position facing the ingot 1 held on the holding table 210. Then, the separation unit 240 causes the suction pad 241 to suction the front surface 1a of the ingot 1 and moves the suction pad 241 upward, thereby separating the substrate W from the peeling layer 2 of the ingot 1.

After the ingot 1 from which the substrate W is separated is ground and/or polished, the slicing step S10 is performed again. Accordingly, a plurality of substrates W are manufactured from the ingot 1.

### Chamfering Step

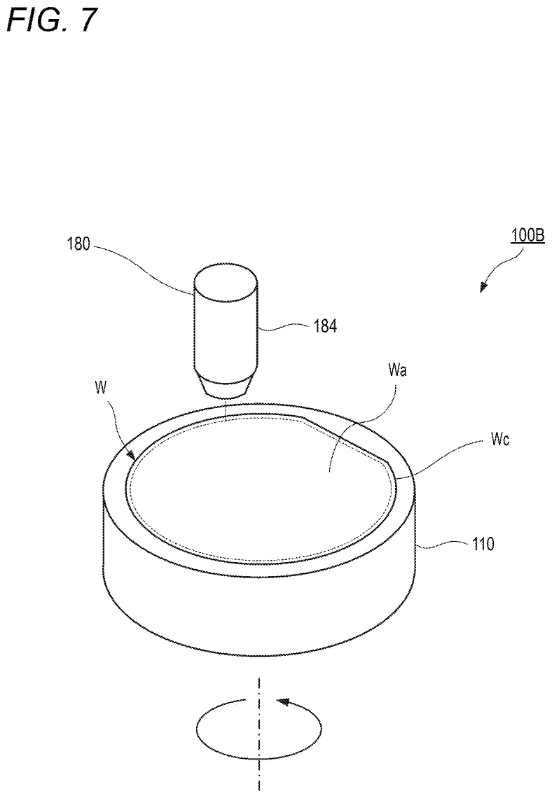

As illustrated in FIGS. 7 to 9, in the chamfering step S20, the chamfered portion Wd is formed at a boundary between the sliced surface Wa and the side surface Wc of the substrate W separated from the ingot 1. Although details will be described later, the chamfering step S20 is performed in order to favorably grind the substrate W in the grinding step S30 (more specifically, the finish grinding step S32).

In the present embodiment, the chamfering step S20 is performed after the slicing step S10 and before the grinding step S30. The chamfering step S20 is performed using the second laser processing device 100B. The configuration of the second laser processing device 100B is denoted by the same reference numbers as the first laser processing device 100A, and a description thereof will be omitted.

In the chamfering step S20, the substrate W is held on the holding table 110 with the sliced surface Wa facing upward. For example, the laser beam emitting mechanism 180 may emit a laser beam from above the sliced surface Wa of the substrate W (see FIG. 8) or may emit a laser beam from a lateral side of the sliced surface Wa of the substrate W (see FIG. 9). The second laser processing device 100B positions the focal point of the laser beam on an outer periphery of the substrate W held on the holding table 110, and emits the laser beam while rotating the holding table 110, thereby forming the chamfered portion Wd over the entire periphery of the substrate W. The wavelength of the laser beam to be emitted is set such that at least a part of the laser beam is absorbed by the substrate W. Emitting conditions of the laser beam can be set as follows, for example.
Wavelength: 355 nm
Average output: 13.5 W
Repetition frequency: 100 kHz

The chamfered portion Wd formed in the chamfering step S20 is formed such that the boundary between the sliced surface Wa and the side surface Wc of the substrate W does not have a right angle shape. For example, the chamfered portion Wd is in contact with the sliced surface Wa and has an inclination surface such that an angle (chamfering angle θ) formed with the sliced surface Wa is larger than 0° and smaller than 90°. The chamfered portion Wd may have a curved surface, or may have both a curved surface and an inclination surface, in addition to having the inclination surface. The chamfering angle θ and a shape of the chamfered portion Wd are adjusted by, for example, controlling an emitting time, an output, a processing speed (rotation speed of the holding table 110), and the like of the laser beam.

### Grinding Step

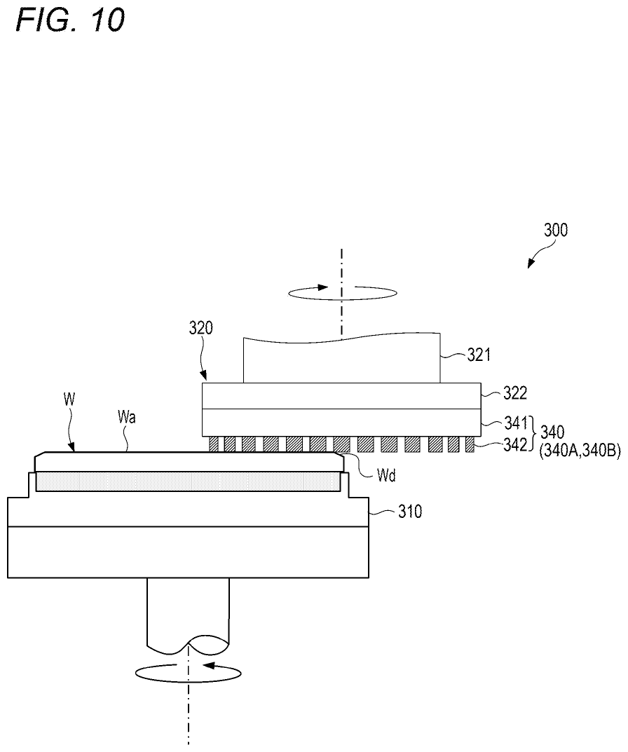

As illustrated in FIG. 10, in the grinding step S30, the sliced surface Wa of the substrate W on which the chamfered portion Wd is formed is ground. The grinding device 300 used in the grinding step S30 includes a holding table 310 that suction-holds the substrate W, and a grinding unit 320 that grinds the substrate W held on the holding table 310. The holding table 310 is connected to a rotation drive source (not illustrated) such as a motor, and is rotatable about a rotation axis perpendicular to the holding surface by operating the rotation drive source. The substrate W is held on the holding table 310 with the sliced surface Wa facing upward.

The grinding unit 320 includes a spindle 321 substantially perpendicular to the holding table 310 and a rotation drive source (not illustrated), such as a motor, for rotating the spindle 321. A wheel mount 322 is fixed to a lower end of the spindle 321, and a grinding wheel 340 is fixed to a lower end of the wheel mount 322. The grinding wheel 340 includes a circular base 341 made of a metal material such as stainless steel or aluminum, and a plurality of grinding stone portions 342 arranged circularly on a lower surface of the base 341. The grinding stone portions 342 contain a binder made of, for example, ceramics, a resin, and a metal material, and numerous abrasive grains such as diamond dispersed and fixed in the binder.

In the present embodiment, the grinding device 300 is provided with a rough grinding wheel 340A and a finish grinding wheel 340B as the grinding wheels 340. In other words, the grinding device 300 is provided with a grinding unit 320 including the rough grinding wheel 340A and a grinding unit 320 including the finish grinding wheel 340B. The finish grinding wheel 340B is a grinding wheel including the grinding stone portion 342 containing finer abrasive grains than the rough grinding wheel 340A.

The grinding step S30 includes the rough grinding step S31 of grinding the sliced surface Wa of the substrate W by the rough grinding wheel 340A, and the finish grinding step S32 performed after the rough grinding step S31 to further grind the sliced surface Wa of the substrate W by the finish grinding wheel 340B.

In the rough grinding step S31, a positional relation between the holding table 310 and the grinding unit 320 is adjusted such that a center of the substrate W held on the holding table 310 overlaps a trajectory of the grinding stone portion 342. Then, in the rough grinding step S31, the rough grinding wheel 340A is lowered along a direction (vertical direction) parallel to a rotation axis of the spindle 321 while rotating the holding table 310 and the rough grinding wheel 340A, and a lower surface of the grinding stone portion 342 is brought into contact with the substrate W held on the holding table 310, thereby starting the rough grinding of the substrate W. In the rough grinding step S31, unevenness of the sliced surface Wa of the substrate W is removed by the rough grinding wheel 340A. In the rough grinding step S31, the substrate W is ground such that the sliced surface Wa becomes substantially flat without forming an inclination surface on the sliced surface Wa of the substrate W.

In the finish grinding step S32, as in the rough grinding step S31, a positional relation between the holding table 310 and the grinding unit 320 is adjusted such that the center of the substrate W held on the holding table 310 overlaps the trajectory of the grinding stone portion 342. Then, in the finish grinding step S32, the finish grinding wheel 340B is lowered along a direction parallel to the rotation axis of the spindle 321 while rotating the holding table 310 and the finish grinding wheel 340B, and the lower surface of the grinding stone portion 342 is brought into contact with the substrate W held on the holding table 310, thereby starting the finish grinding of the substrate W. In the finish grinding step S32, a surface roughness of the sliced surface Wa of the substrate W is reduced.

Grinding conditions of the rough grinding step S31 and the finish grinding step S32 can be set as follows, for example.
Rough grinding step
   Spindle (grinding wheel) rotation speed: 2,000 rpm
   Holding table rotation speed: 41 rpm
   Spindle lowering feed rate: 1.0 μm/s
Finish grinding step
   Spindle (grinding wheel) rotation speed: 2,500 rpm
   Holding table rotation speed: 301 rpm
   Spindle lowering feed rate: 0.25 μm/s

The spindle lowering feed rate in the rough grinding step S31 is larger than that in the finish grinding step S32, that is, a grinding rate (grinding amount per unit time) in the rough grinding step S31 is larger than that in the finish grinding step S32. Accordingly, a processing time for the rough grinding step S31 can be shortened.

Here, the operation and effect of performing the chamfering step S20 before the grinding step S30 will be described. When a substrate having a substantially flat sliced surface and on which no chamfered portion Wd is formed is ground, the grinding stone portion 342 of the finish grinding wheel 340B containing fine abrasive grains is less likely to bite into the substrate. In this case, the progress of finish grinding is poor, and a grinding load on the substrate increases. In order to solve such a problem, for example, in the rough grinding step S31, the sliced surface of the substrate may be ground at an inclination angle. By such grinding, for example, a substrate having a convex shape with a thick central portion and a thin outer periphery or a substrate having a concave shape with a thin central portion and a thick outer periphery is formed. However, when the finish grinding step S32 is performed on such a substrate, the substrate is subjected to additional finish grinding for the inclined portion, resulting in an increased loss of material.

In the grinding step S30 of the present embodiment, even when the sliced surface Wa of the substrate W on which the chamfered portion Wd is formed is ground, and thus even if the sliced surface Wa is flat, the grinding stone portion 342 is appropriately worn when the grinding stone portion 342 comes into contact with the chamfered portion Wd at an initial stage in either rough grinding or finish grinding, and the grinding stone portion 342 bites into the substrate W. Accordingly, good grinding can be achieved without increasing the grinding load on the substrate W. There is no need to incline the sliced surface Wa of the substrate W, and thus the loss of material during grinding can be decreased.

An experiment performed to confirm a relation between the chamfering angle θ of the chamfered portion Wd and the grinding load will be described. In this experiment, six substrates W having chamfering angles θ of 0° (no chamfered portion Wd), 15°, 30°, 45°, 60°, and 75° were prepared, and the grinding was performed using the finish grinding wheel 340B. Grinding conditions were the same as those in the finish grinding step S32, and the grinding amount was about 10 μm at any chamfering angle θ. Results of a maximum grinding load [N] (maximum value of the load applied to the substrate W during the finish grinding) and a thickness [μm] of the substrate W before and after the grinding for each chamfering angle θ are shown in the following table.

TABLE 1

| | | Substrate | Substrate |
|---|---|---|---|
| | Maximum | thickness | thickness |
| Chamfering | grinding | before | after |
| angle [°] | load [N] | grinding [μm] | grinding [μm] |
| 0 (right | 361.5 | 370.3 | 360.0 |
| angle) | | | |
| 15 | 195.5 | 358.9 | 349.1 |
| 30 | 170.5 | 317.4 | 307.7 |
| 45 | 171.3 | 374.2 | 364.5 |
| 60 | 171.8 | 486.6 | 477.4 |
| 75 | 188.8 | 411.1 | 401.4 |

When a case in which the chamfered portion Wd was formed and a case in which no chamfered portion Wd was formed (chamfering angle θ was) 0° were compared with each other, it was confirmed that the maximum grinding load was decreased by forming the chamfered portion Wd. In this way, by forming the chamfered portion Wd such that the boundary between the sliced surface Wa and the side surface Wc of the substrate W does not have a right angle shape, good finish grinding may be performed without increasing the grinding load on the substrate W.

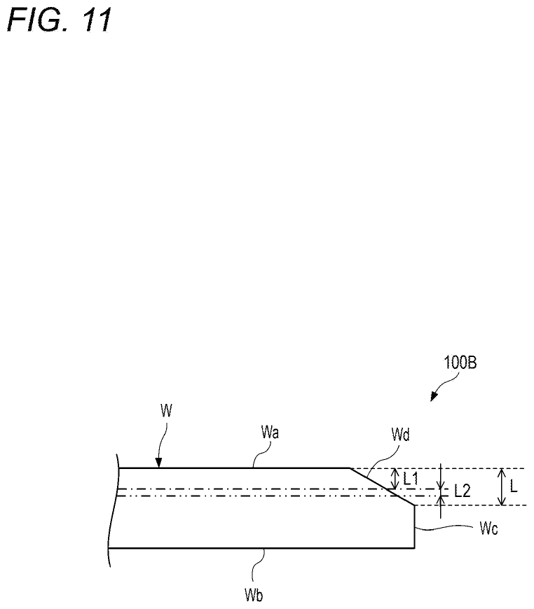

As illustrated in FIG. 11, in the chamfering step S20, a length L of the chamfered portion Wd in the thickness direction of the substrate W is set based on the grinding amount when the grinding is performed in the grinding step S30. In FIG. 11, a distance L1 from the sliced surface Wa of the substrate W to a one-dot chain line is a grinding amount of the rough grinding step S31 in the thickness direction. A distance L2 from the one-dot chain line to a two-dot chain line is a grinding amount of the finish grinding step S32 in the thickness direction.

As an example of the setting of the length L of the chamfered portion Wd based on the grinding amount, the length L of the chamfered portion Wd in the thickness direction is larger than the grinding amount (distance L1) of the rough grinding step S31 in the thickness direction, and the chamfered portion Wd remains after the rough grinding step S31 is performed. Accordingly, the finish grinding step S32 is performed on the substrate W on which the chamfered portion Wd remains, and thus the finish grinding wheel 340B containing fine abrasive grains can also appropriately bite into the substrate W.

As another example of the setting of the length L of the chamfered portion Wd based on the grinding amount, the length L of the chamfered portion Wd in the thickness direction is larger than the grinding amounts (sum of the distance L1 and the distance L2) of the rough grinding step S31 and the finish grinding step S32 in the thickness direction, and the chamfered portion Wd remains after the finish grinding step S32 is performed. Accordingly, the substrate W including the chamfered portion Wd can be manufactured without separately providing a step of forming the chamfered portion Wd on the substrate W after the finish grinding step S32.

### Polishing Step

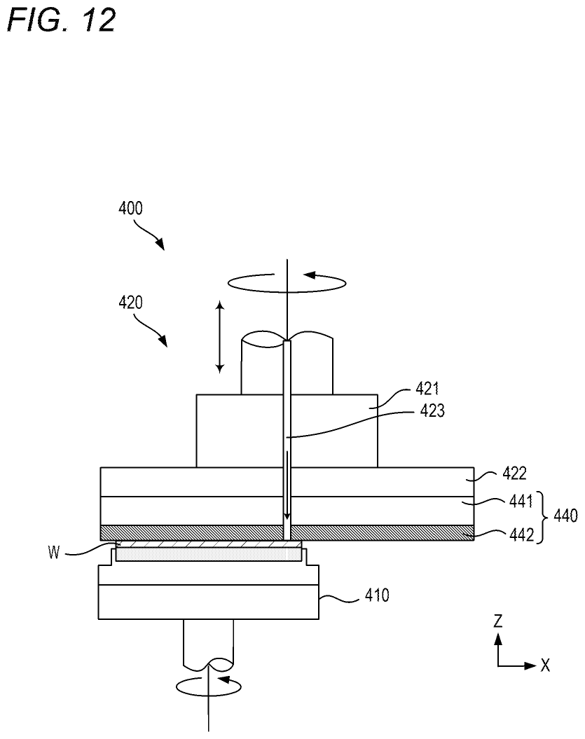

FIG. 12 is a diagram illustrating the polishing step S40. The polishing device 400 used in the polishing step S40 includes a holding table 410 that suction-holds the substrate W, and a polishing unit 420 that polishes the substrate W held on a holding surface of the holding table 410. The holding table 410 is connected to a rotation drive source (not illustrated) such as a motor, and is rotatable about a rotation axis perpendicular to the holding surface by operating the rotation drive source. The substrate W is held on the holding table 410 with the sliced surface Wa (ground surface) facing upward.

The polishing unit 420 includes a spindle 421 substantially perpendicular to the holding surface of the holding table 410 and a rotation drive source (not illustrated), such as a motor, for rotating the spindle 421. A wheel mount 422 is fixed to a lower end of the spindle 421, and a polishing wheel 440 is fixed to a lower end of the wheel mount 422.

The polishing wheel 440 includes a platen 441 made of a hard resin, and a polishing pad 442 fixed to a lower surface side of the platen 441. The polishing pad 442 includes, for example, a hard polyurethane foam or a nonwoven fabric. When the substrate W is polished by the polishing pad 442, the substrate W is polished using a polishing agent (slurry).

The polishing wheel 440 is disposed concentrically with the spindle 421 and the wheel mount 422. A through hole 423 penetrating the polishing pad 442, the platen 441, the wheel mount 422, and the spindle 421 is formed in a central portion of the polishing wheel 440 in a radial direction. A polishing agent supply source (not illustrated) is connected to an upper end portion of the through hole 423. The through hole 423 functions as a polishing agent supply path that supplies a polishing agent to the substrate W and the polishing pad 442 when the substrate W is polished by the polishing pad 442.

In the polishing step S40, the substrate W is suction-held on the holding table 410, and the holding table 410 is disposed below the polishing wheel 440. Then, in the polishing step S40, the spindle 421 and the holding table 410 are rotated at different rotation speeds, respectively, and the polishing pad 442 is lowered while supplying the polishing agent to the substrate W and a lower surface of the polishing pad 442 from the through hole 423. In the polishing step S40, the polishing pad 442 is pressed against the substrate W at a predetermined pressure to press the lower surface of the polishing pad 442 against the sliced surface Wa of the substrate W. In this way, the sliced surface Wa of the substrate Wis polished, and the substrate W is polished to a mirror finish.

### Chip Manufacturing Method

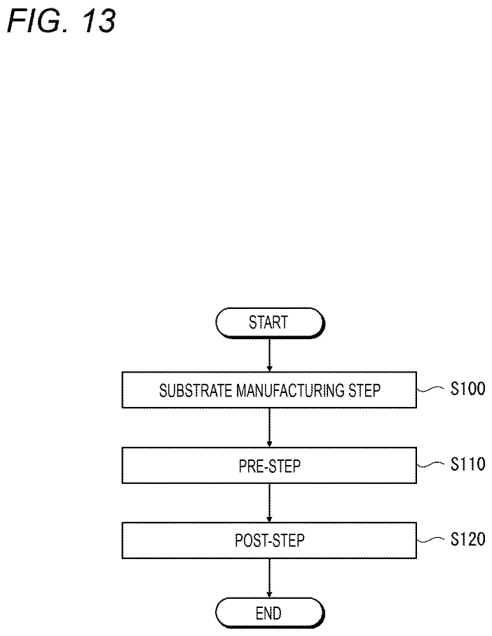

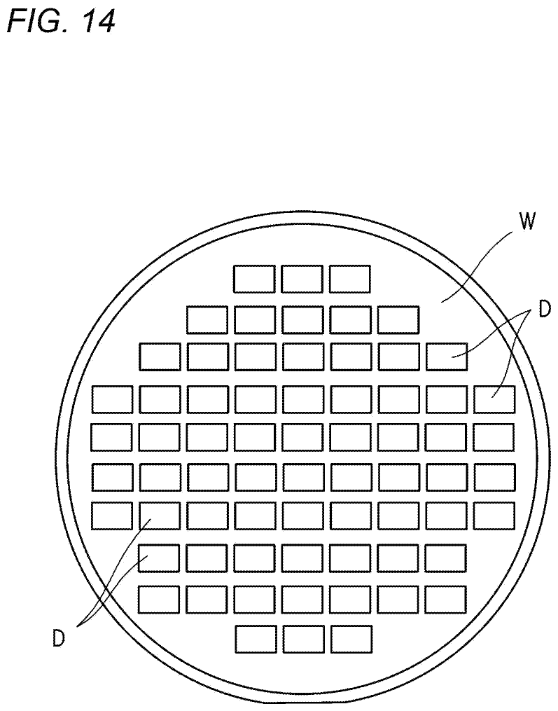

FIG. 13 is a flowchart of an embodiment of the chip manufacturing method. The chip manufacturing method of the present embodiment includes, for example, a substrate manufacturing step S100, a pre-step S110, and a post-step S120. The substrate manufacturing step S100 is a step of manufacturing the substrate W by using the method for manufacturing the substrate W. The pre-step S110 is a step of forming a circuit on the substrate W and manufacturing a plurality of semiconductor devices D on the substrate W. The semiconductor device D is, for example, a device such as an integrated circuit (IC), a large scale integration (LSI), a light emitting diode (LED), or micro electro mechanical systems (MEMS). FIG. 14 is a diagram illustrating the substrate W on which the plurality of semiconductor devices D are formed. The post-step S120 is a step of assembling a semiconductor chip, in which, after the substrate W on which a plurality of semiconductor devices are formed is cut, wiring and resin encapsulation are performed to manufacture a semiconductor chip. The substrate W may be cut using a cutting blade or a laser processing device.

Although the embodiment of the present disclosure has been described above with reference to the accompanying drawings, it is needless to say that the present disclosure is not limited to this embodiment. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

For example, the substrate manufacturing method of the above embodiment has been described by taking the case in which the workpiece is the ingot 1 as an example, but the present disclosure is not limited thereto, and the workpiece may be a substrate, for example. That is, one substrate may be further divided into a plurality of substrates by performing the substrate manufacturing method of the above embodiment on the one substrate.

In the above embodiment, the chamfering step S20 is performed before the grinding step S30 (specifically, before the rough grinding step S31), but the present disclosure is not limited thereto. Specifically, the chamfering step S20 may be performed during the grinding step S30, and specifically, may be performed after the rough grinding step S31 and before the finish grinding step S32. With this configuration, the sliced surfaces Wa of the substrates W can be ground well in the finish grinding step S32.

The present specification describes at least the following matters. Corresponding components and the like in the embodiments described above are shown in parentheses as an example, but the present disclosure is not limited thereto.

(1) A substrate manufacturing method for manufacturing a substrate (substrate W) thinner than a workpiece (ingot 1) having a main surface and a side surface from the workpiece, the method including:
separating (slicing step S10) the substrate from the workpiece;
forming (chamfering step S20) a chamfered portion (chamfered portion Wd) at a boundary between a sliced surface (sliced surface Wa) and a side surface (side surface Wc) of the separated substrate; and
grinding (grinding step S30) the sliced surface with a grinding wheel (grinding wheel 340), in which
the forming is performed after the slicing and before the grinding or during the grinding, and
in the grinding, the sliced surface of the substrate on which the chamfered portion is formed is ground.

According to (1), the grinding is performed on the substrate on which the chamfered portion is formed, even if no inclination surface is formed on the sliced surface of the substrate, the grinding stone portion of the grinding wheel wears moderately when the grinding stone portion comes into contact with the chamfered portion, and the grinding stone portion bites into the substrate. Therefore, there is no need to incline the sliced surface of the substrate, and thus the loss of material during grinding can be decreased.

(2) The substrate manufacturing method according to (1), in which
the grinding includes:
   first grinding (rough grinding step S31) including grinding the sliced surface of the substrate with a first grinding wheel (rough grinding wheel 340A) having a grinding stone portion (grinding stone portion 342); and
   second grinding (finish grinding step S32) performed after the first grinding to grind the sliced surface of the substrate with a second grinding wheel (finish grinding wheel 340B) having a grinding stone portion containing finer abrasive grains than the first grinding wheel, and
the forming is performed before the second grinding.

According to (2), at least the second grinding step is performed on the substrate on which the chamfered portion is formed, and thus the grinding can also be performed sufficiently with the second grinding wheel having the grinding stone portion containing fine abrasive grains.

(3) The substrate manufacturing method according to (2), in which
in the forming, a length of the chamfered portion in a thickness direction of the substrate is set based on a grinding amount when grinding in the grinding.

According to (3), the length of the chamfered portion in the thickness direction can be appropriately set based on the grinding amount.

(4) The substrate manufacturing method according to (3), in which
the forming is performed before the first grinding, and
the length of the chamfered portion in the thickness direction is larger than a grinding amount in the first grinding in the thickness direction, and thus the chamfered portion remains after the first grinding is performed.

According to (4), the second grinding is performed on the substrate on which the chamfered portion remains, and thus the second grinding wheel containing fine abrasive grains can also appropriately bite into the substrate.

(5) The substrate manufacturing method according to (3), in which
the forming is performed before the first grinding, and
the length of the chamfered portion in the thickness direction is larger than grinding amounts in the first grinding and the second grinding in the thickness direction, and thus the chamfered portion remains after the second grinding is performed.

According to (5), the substrate including the chamfered portion can be manufactured without separately providing a step of forming the chamfered portion on the substrate after the second grinding.

(6) The substrate manufacturing method according to (1), in which
the slicing includes:
   emitting a laser beam having a wavelength that penetrates the workpiece from a front surface of the workpiece, positioning a focal point of the laser beam at a position deeper than the front surface of the workpiece, and processing and feeding the workpiece and the focal point relative to each other to form a peeling layer (peeling layer 2) inside the workpiece; and
   peeling off the substrate from the peeling layer.

According to (6), the slicing can be performed by laser processing.

(7) The substrate manufacturing method according to (1), in which
in the forming, the chamfered portion is formed by irradiating the substrate with a laser beam whose focal point is positioned on an outer periphery of the substrate.

According to (7), the forming can be performed by the laser processing.

(8) The substrate manufacturing method according to any one of (1) to (7), in which
in the forming, the chamfered portion is formed such that the boundary between the sliced surface and the side surface of the separated substrate does not have a right angle shape.

According to (8), the grinding can be performed such that the grinding stone portion of the grinding wheel certainly bites into the substrate.

(9) A chip manufacturing method comprising:
manufacturing (substrate manufacturing step S100) a substrate (substrate W) by using the substrate manufacturing method according to any one of (1) to (8);
manufacturing (pre-step S110) a plurality of semiconductor devices on the substrate; and
manufacturing (post-step S120) a semiconductor chip by cutting the substrate on which the plurality of semiconductor devices are formed.

According to (9), in the manufacturing of the substrate in the chip manufacturing method, the loss of material of the substrate during grinding can be decreased.

(10) A processing device (substrate manufacturing device 10) for processing a sliced surface of a substrate separated from a workpiece having a main surface and a side surface, the processing device including:
a chamfered portion forming device (second laser processing device 100B) configured to form a chamfered portion at a boundary between the sliced surface and a side surface of the separated substrate;
   and
a grinding device (grinding device 300) configured to grind the sliced surface with a grinding wheel, in which
the chamfered portion forming device forms the chamfered portion before the substrate is ground by the grinding device or during grinding of the substrate by the grinding the grinding device grinds the sliced surface of the substrate on which the device, and chamfered portion is formed.

According to (10), the grinding is performed on the substrate on which the chamfered portion is formed, even if no inclination surface is formed on the sliced surface of the substrate, the grinding stone portion of the grinding wheel wears moderately when the grinding stone portion comes into contact with the chamfered portion, and the grinding stone portion bites into the substrate. Therefore, there is no need to incline the sliced surface of the substrate, and thus the loss of material during grinding can be decreased.

1. A substrate manufacturing method for manufacturing a substrate thinner than a workpiece having a main surface and a side surface from the workpiece, the substrate manufacturing method comprising:
separating the substrate from the workpiece;
forming a chamfered portion at a boundary between a sliced surface and a side surface of the separated substrate; and
grinding the sliced surface with a grinding wheel, wherein
the forming is performed after the separating and before the grinding or during the grinding, and
in the grinding, the sliced surface of the substrate on which the chamfered portion is formed is ground.

2. The substrate manufacturing method according to claim 1, wherein
the grinding includes:
first grinding including grinding the sliced surface of the substrate with a first grinding wheel having a grinding stone portion; and
second grinding performed after the first grinding to grind the sliced surface of the substrate with a second grinding wheel having a grinding stone portion containing finer abrasive grains than the first grinding wheel, and
the forming is performed before the second grinding.

3. The substrate manufacturing method according to claim 2, wherein
in the forming, a length of the chamfered portion in a thickness direction of the substrate is set based on a grinding amount when grinding in the grinding.

4. The substrate manufacturing method according to claim 3, wherein
the forming is performed before the first grinding, and
the length of the chamfered portion in the thickness direction is larger than a grinding amount in the first grinding in the thickness direction, and thus the chamfered portion remains after the first grinding is performed.

5. The substrate manufacturing method according to claim 3, wherein
the forming is performed before the first grinding, and
the length of the chamfered portion in the thickness direction is larger than grinding amounts in the first grinding and the second grinding in the thickness direction, and thus the chamfered portion remains after the second grinding is performed.

6. The substrate manufacturing method according to claim 1, wherein
the separating includes:
emitting a laser beam having a wavelength that penetrates the workpiece from a front surface of the workpiece, positioning a focal point of the laser beam at a position deeper than the front surface of the workpiece, and processing and feeding the workpiece and the focal point relative to each other to form a peeling layer inside the workpiece; and
peeling off the substrate from the peeling layer.

7. The substrate manufacturing method according to claim 1, wherein
in the forming, the chamfered portion is formed by irradiating the substrate with a laser beam whose focal point is positioned on an outer periphery of the substrate.

8. The substrate manufacturing method according to claim 1, wherein
in the forming, the chamfered portion is formed such that the boundary between the sliced surface and the side surface of the separated substrate does not have a right angle shape.

9. A chip manufacturing method comprising:
manufacturing a substrate by using the substrate manufacturing method according to claim 1;
manufacturing a plurality of semiconductor devices on the substrate; and
manufacturing a semiconductor chip by cutting the substrate on which the plurality of semiconductor devices are formed.

10. A processing device for processing a sliced surface of a substrate separated from a workpiece having a main surface and a side surface, the processing device comprising:
a chamfered portion forming device configured to form a chamfered portion at a boundary between the sliced surface and a side surface of the separated substrate; and
a grinding device configured to grind the sliced surface with a grinding wheel, wherein
the chamfered portion forming device forms the chamfered portion before the substrate is ground by the grinding device or during grinding of the substrate by the grinding device, and
the grinding device grinds the sliced surface of the substrate on which the chamfered portion is formed.
